(19) United States
(12) Patent Application Publication
(10) Pub. No.: US 2007/0042574 A1
(43) Pub. Date: Feb. 22, 2007

(54) Method for manufacturing a semiconductor device

(75) Inventors: Norishiro Komatsu, Tokyo (JP); Toshiyuki Hirota, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/503,968

(22) Filed: Aug. 15, 2006

(30) Foreign Application Priority Data
Aug. 19, 2005 (JP) 2005-238216

(51) Int. Cl. H01L 21/00

(52) U.S. Cl. 438/482

(57) ABSTRACT

A method for manufacturing a semiconductor device that can prevent short-circuiting between gate electrodes and increases in the leakage current of a capacitive insulating film caused by the bottom electrode of the capacitor is provided. The method for manufacturing a semiconductor device according to the present invention comprises a first step for forming an amorphous silicon film on a semiconductor substrate; a second step for forming a stopper film on a surface of the amorphous silicon film to prevent migration of the surface of the amorphous silicon film; and a third step for removing the stopper film from the surface of the amorphous silicon film.

### TECHNICAL FIELD

The present invention relates to a method for manufacturing a semiconductor device, and to a method for manufacturing a semiconductor device using an amorphous silicon film in the formation of gate electrodes and bottom electrodes of capacitors.

### BACKGROUND OF THE INVENTION

Over the past several years, semiconductor devices have undergone higher levels of integration and have been fabricated at increasingly small scales. For example, mass production has already begun on 1 Gbit high-capacity memory DRAMs (Dynamic Random Access Memory), and 2 Gbit high capacity memories have also been commercialized. The basic structure of a DRAM memory cell has one gate transistor and one capacitor. Polysilicon is already used as the material for the gate electrode of a gate transistor and the bottom electrode of a capacitor. The design rules for DRAMs are, for example, 0.11 μm for 1 Gbit DRAMs and 0.084 μm for 2 Gbit DRAMs, with the fabrication dimensions being made smaller each year. This has been accompanied by the need to maintain precise control of the surface or interface condition of polysilicon, uniformity of film thickness, and dimensions of worked shapes in gate electrodes and capacitor electrodes. Fluctuations in thickness and fabrication dimensions cause discrepancies in electrical performance of the end product. Therefore, controlling the surface or interface condition of the surface and interfaces of amorphous (non-crystalline) polysilicon is going to become increasingly important in the future for gate electrodes and capacitor electrodes.

Specifically, methods conventionally used to form polysilicon doped with phosphorus (P) involve forming amorphous silicon at a relatively low temperature of about 500° C., and subsequently subjecting the silicon to a heat treatment to obtain polysilicon in order to improve thickness uniformity as well as the surface condition (so as to minimize surface roughness and surface irregularity through P-doping).

A gate electrode is cited by way of example in the description below. The demand for greater processing speed and reduced power consumption in MOSFETs used in DRAM memory cells and the like makes it imperative for the gate electrode to have low resistance. Conventionally, therefore, a polycide structure has been adopted wherein tungsten silicide (WSi) is layered on a polysilicon film. However, gate electrodes having a polymetal structure (polymetal gates) wherein a refractory metal (e.g., tungsten (W)) is layered have come to be employed over the past several years.

In a DRAM polymetal gate, first, an amorphous silicon film is formed by LP-CVD (low pressure-chemical vapor deposition) on a gate insulating film on a semiconductor substrate, a metal film (e.g., tungsten) and a cap insulating film are formed thereon, the cap insulating film is then patterned into the shape of a gate-electrode by photomasking, and a metal film and a silicon film are then formed by dry etching. The amorphous silicon film is poly-crystallized by a heat treatment performed before or after the metal film is formed, and a polysilicon film is formed. As with an amorphous silicon film, a polysilicon film formed by poly-crystallizing amorphous silicon is also suitable for micro-fabrication because substantially no surface irregularities will be present. However, the use of amorphous silicon films presents the following problems.

The monosilane (SiH₄) or other reaction gas and unreacted gas (or gas mixtures thereof) used in the formation of the amorphous silicon film are exhausted from the reaction chamber of the LP-CVD apparatus immediately after the film has been formed, and the reaction chamber is purged using an inert gas. Unreacted SiH₄ gas (line gas) remaining in the gas piping through which reaction gas is supplied to the gas chamber must also be exhausted and purged using an inert gas (gas line purge). For this reason, the semiconductor substrate (Si wafer) cannot be removed from the reaction chamber immediately after film formation. Specifically, due to the fact that precise control of gas flow amount is necessary, recent gas-feed system units containing gas piping have had complex structures. If the gas line is inadequately purged, unreacted gas will remain in the dead space within the gas-feed system unit, and fine particles will inevitably form due to a gas phase reaction in the supply system unit, or, when film formation commences, in the nozzle of the reaction tube. For this reason, sufficient attention must be given when the gas line is purged so that unreacted gas does not remain inside the gas-feed system unit, purging and discharging must be repeatedly conducted several times, and a relatively long period of time (e.g., about 30 to 40 minutes) must be spent to completely exhaust gas from inside the feed system unit. The pressure within the reaction chamber is kept low (about 1 to 90 Pa) during this relatively long period of time.

Minute silicon nuclei readily form on the surface of the amorphous silicon film under low-pressure conditions after film formation, and, if a low-pressure environment is maintained for a relatively long period of time, the surface of the amorphous silicon film will become highly prone to migration, and the minute silicon nuclei will gradually grow (secondary growth). A partial cross-sectional view of this state is shown in FIG. 13A. Large silicon nuclei 302n are formed on the surface of the amorphous silicon film 302a that is formed on the gate insulating film 301 on the semiconductor device 300, as shown in FIG. 13A.

When a metal film 303 and a cap insulating film 304 are formed on such a silicon film 302 (an amorphous silicon film 302a or a poly-crystallized silicon film thereof), on whose surface silicon nuclei 302n have formed, the metal film and cap insulating film 304 layered thereon are formed in a way that directly reflects the irregular state of the surface of the silicon film 302, as shown in FIG. 13B. These irregularities appear large because they have been magnified in width (lens effect) due to the laminar structure of the metal film and the insulating film thereon.

Therefore, when such a layered film having the silicon film 302, metal film 303, and cap insulating film 304 is patterned via anisotropic etching to form a gate electrode 305 as shown in FIG. 13C, the silicon film 302 and metal film 303 will protrude from the pattern of the gate electrode and end up incompletely etched on the lower part of the gate electrode 305. The silicon nuclei 302n have been confirmed to grow to a grain diameter d (see FIG. 13B) of about 80 to 100 nm. Therefore, and particularly if the spacing s between the gate electrodes (see FIG. 13C) is very fine; e.g., about 100 nm, a problem will be presented in that short-circuiting will inevitably occur between adjacent gate electrodes 305.

The bottom electrode for a cylinder-type capacitor is cited by way of example in the discussion below. Over the past several years, the chips used in high-capacity memory (2 Gbit or greater) have become progressively smaller in capacitors used in DRAM cells and the like, and demand is increasing for achieving higher levels of integration while preserving the capacitor capacity at conventional levels. Capacitor capacity is addressed by using a high-k dielectric for the insulating film, ensuring a certain surface area within the capacitor, and adopting other measures. However, the capacitors constituting the memory cell must be arranged at a high density within a limited area, and the polysilicon film used for the bottom electrode of the capacitor must be made thinner.

The method used to form the polysilicon of the bottom electrode of the capacitor is fundamentally the same as that used for the polysilicon of the polymetal gate electrode described above. In other words, first, a silicon film is formed in an amorphous state, and the resulting film is subjected to a heat treatment to become polysilicon. However, a structure is used in the polysilicon of a gate electrode wherein a capacitive insulating film rather than a metal film is layered on the polysilicon of the bottom electrode of the capacitor.

In addition, an HSG (hemispherical grain) treatment is performed on the surface of the bottom electrode in order to ensure a larger electrical capacitance. The silicon film (the bottom electrode) must first be formed in an amorphous state in order for the surface of the bottom electrode to be subjected to an HSG treatment. The silicon film is then kept under a relatively low pressure for a relatively long period of time in the same manner as described above. Therefore, surface migration occurs on the amorphous silicon film, and secondary growth of silicon nuclei occurs on the surface, which results in irregularities forming on the surface of the amorphous silicon film. Therefore, when the HSG treatment is performed on the surface of the amorphous silicon in the next step, the shapes of the grains will not be uniformly arranged, and large and small hemispherical grains will ultimately be formed. Specifically, the silicon nuclei that have already undergone secondary growth on the amorphous silicon film will become unusually large.

When the thickness of the amorphous silicon film that constitutes the bottom electrode decreases in subsequent procedures oriented towards further reductions in scale, variations in the shapes and sizes of the hemispherical grains and non-uniform irregularities in the surface will lead to local electric field concentration readily occurring on the bottom electrode, and an increased leak current will be more likely to flow in the capacitive insulating film formed on the electrode.

Methods of manufacturing a semiconductor device using an amorphous silicon film in the formation of gate electrodes and bottom electrodes of capacitors are described in, for example, Japanese Patent application Laid-open Nos. S63-4670 and 2000-150509. Japanese Patent Application Laid-open No. 2000-174027 describes a method of taking out treated object from heat treatment equipment.

### SUMMARY OF THE INVENTION

The present invention was developed in order to overcome the abovementioned problems, and an object of the invention is to provide a method for manufacturing a semiconductor device whereby it is possible to prevent short-circuiting between gate electrodes and to prevent increases in the leakage current of a capacitive insulating film caused by the bottom electrode of the capacitor.

The method for manufacturing a semiconductor device according to the present invention comprises a first step for forming an amorphous silicon film on a semiconductor substrate; a second step for forming a stopper film on a surface of the amorphous silicon film to prevent migration of the surface of the amorphous silicon film; and a third step for removing the stopper film from the surface of the amorphous silicon film.

According to the present invention, an amorphous silicon film is formed, and a stopper film that covers the surface thereof is subsequently formed. As a result, after the amorphous silicon film is formed, migration on the surface of the amorphous silicon film can be prevented and secondary growth of minute silicon nuclei thereon can be minimized even when the film is kept in a low-pressure reaction chamber for long periods of time. Accordingly, the surface of the amorphous silicon film will be substantially devoid of irregularities, and it will be possible to keep the amorphous silicon film so that the surface is in a smooth state.

Therefore, when this amorphous silicon film is used in a polymetal gate, removing the stopper film before the metal film is formed on the amorphous silicon film will make it possible to form a metal film on the smooth-surfaced amorphous silicon film (or polysilicon film if a heat treatment has been performed), the layered film comprising the silicon film to be readily patterned, and short-circuiting between the gate electrodes to be prevented.

In addition, when the abovementioned amorphous silicon film is used as the bottom electrode of a capacitor, removing the stopper film prior to the HSG treatment will enable an HSG treatment to be performed on an amorphous silicon film whose surface is substantially devoid of irregularities. Therefore, the sizes and shapes of the numerous resulting hemispherical grains can be made substantially uniform, local electric field concentration can be prevented, and the leakage current of the capacity insulation film can be minimized.

### BRIEF DESCRIPTION OF THE DRAWINGS [0020]

The above and other objects, features and advantages of this invention will become more apparent by reference to the following detailed description of the invention taken in conjunction with the accompanying drawings, wherein:

FIG. 1 is a partial cross-sectional view showing one step (from forming the element-separating insulating film 100i to forming the gate insulation film 101) of the method for manufacturing a semiconductor device according to a first embodiment of the present invention;

FIG. 2 is a partial cross-sectional view showing one step (forming the amorphous silicon film 102) of the method for manufacturing a semiconductor device according to the first embodiment of the present invention;

FIG. 3 is a partial cross-sectional view showing one step (forming the silicon oxide film 10) of the method for manufacturing a semiconductor device according to the first embodiment of the present invention;

FIG. 4 is a partial cross-sectional view showing one step (from removing the silicon oxide film 10 to forming the metal film 103) of the method for manufacturing a semiconductor device according to the first embodiment of the present invention;

FIG. 5 is a partial cross-sectional view showing one step (forming the cap insulating film 104) of the method for manufacturing a semiconductor device according to the first embodiment of the present invention;

FIG. 6 is a partial cross-sectional view showing one step (forming the gate electrode 105) of the method for manufacturing a semiconductor device according to the first embodiment of the present invention;

FIG. 7 is a partial cross-sectional view showing one step (from forming the element-separating insulation film 200i to forming the cylinder interlayer film 210) of the method for manufacturing a semiconductor device according to a second embodiment of the present invention;

FIG. 8 is a partial cross-sectional view showing one step (forming the cylinder hole 211) of the method for manufacturing a semiconductor device according to the second embodiment of the present invention;

FIG. 9 is a partial cross-sectional view showing one step (from forming the amorphous silicon films 212, 213 to forming the silicon oxide film 20) of the method for manufacturing a semiconductor device according to the second embodiment of the present invention;

FIG. 10 is a partial cross-sectional view showing one step (etching and removing the silicon oxide film 20 and amorphous silicon films 212, 213 on the cylinder interlayer film) of the method for manufacturing a semiconductor device according to the second embodiment of the present invention;

FIG. 11 is a partial cross-sectional view showing one step (removing the silicon oxide film 20) of the method for manufacturing a semiconductor device according to the second embodiment of the present invention;

FIG. 12 is a partial cross-sectional view showing one step (performing the HSG treatment on the amorphous silicon film 213) of the method for manufacturing a semiconductor device according to the second embodiment of the present invention; and

FIG. 13 is a partial cross-sectional view for explaining the problematic aspects encountered with conventional methods for manufacturing a semiconductor device.

### DETAILED DESCRIPTION OF THE EMBODIMENTS

Preferred embodiments of the present invention will now be explained in detail with reference to the drawings.

(First Embodiment)

As a first embodiment, a description shall be provided of the present invention used in the polymetal gate electrode as an example.

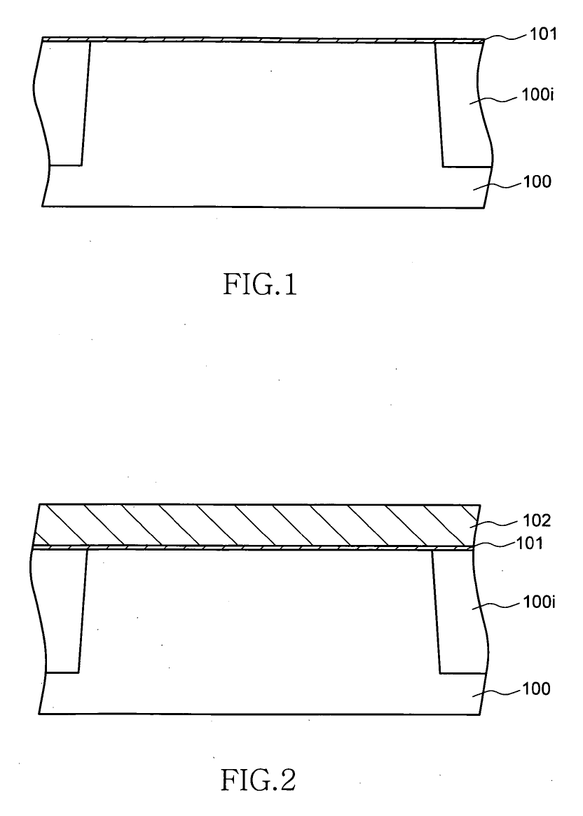

FIGS. 1 through 6 are partial cross-sectional views of the steps of a method for manufacturing a semiconductor device according to a first embodiment of the present invention.

First, as shown in FIG. 1, an element-separating insulation film 100i is formed on a semiconductor substrate 100 using an existing STI (Shallow Trench Isolation) formation technique or other method, and then a gate insulation film 101 is formed on all surfaces by thermal oxidation.

Next, as shown in FIG. 2, a silicon film 102 is formed in a non-crystalline (amorphous) state on the gate insulating film 101. The silicon film 102 may either be doped with impurities or not doped with impurities.

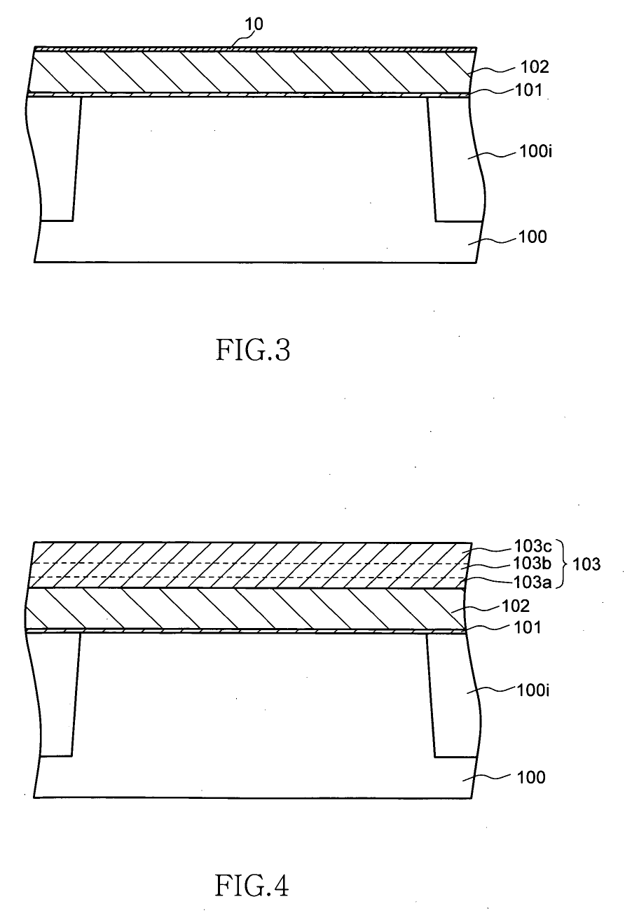

As is shown in FIG. 3, a silicon oxide film 10 is then formed as a stopper film on the surface of the amorphous silicon film 102 to minimize surface migration after the amorphous silicon film 102 has been formed, and to prevent secondary growth of the minute silicon nuclei. The thickness of the silicon oxide film 10 is preferably set to about 0.5 nm or greater. If the thickness of the silicon oxide film 10 is less than 0.5 nm, the risk arises that the film will function inadequately as a stopper for minimizing surface migration in the amorphous silicon film. If the film functions adequately as a stopper film, it need not be made excessively thick. A thickness of 1.5 nm or less is preferable in order to avoid inadequate electroconductivity between the silicon film 102 and the metal film 103 on the silicon film (see FIG. 4) due to residues when the stopper film is subsequently removed.

Next, as shown in FIG. 4, the silicon oxide film 10 is removed by acid cleaning, and the metal film 103 is subsequently formed on the amorphous silicon film 102. The metal film 103 comprises a layered film having a WSi (tungsten silicide) film 103a, WN (tungsten nitride) film 103b, and W (tungsten) film 103c. This layered film is formed, first, by depositing the WSi film 103a on the amorphous silicon film 102 by CVD; then performing a heat treatment (RTA (rapid thermal annealing)) at a temperature of about 900° C. for about one minute in an N₂ atmosphere as a so-called degassing treatment, whereby chlorine or fluorine gas or other gas remaining inside the WSi film is released to the exterior; and subsequently depositing the WN (tungsten nitride) film 103b and the w (tungsten) film 103c in the stated order by sputtering. The impurities contained in the silicon film 102 are activated and, at the same time, the silicon film 102 is changed from a non-crystalline to a poly-crystalline state by the heat treatment for degassing the abovementioned WSi film 103a.

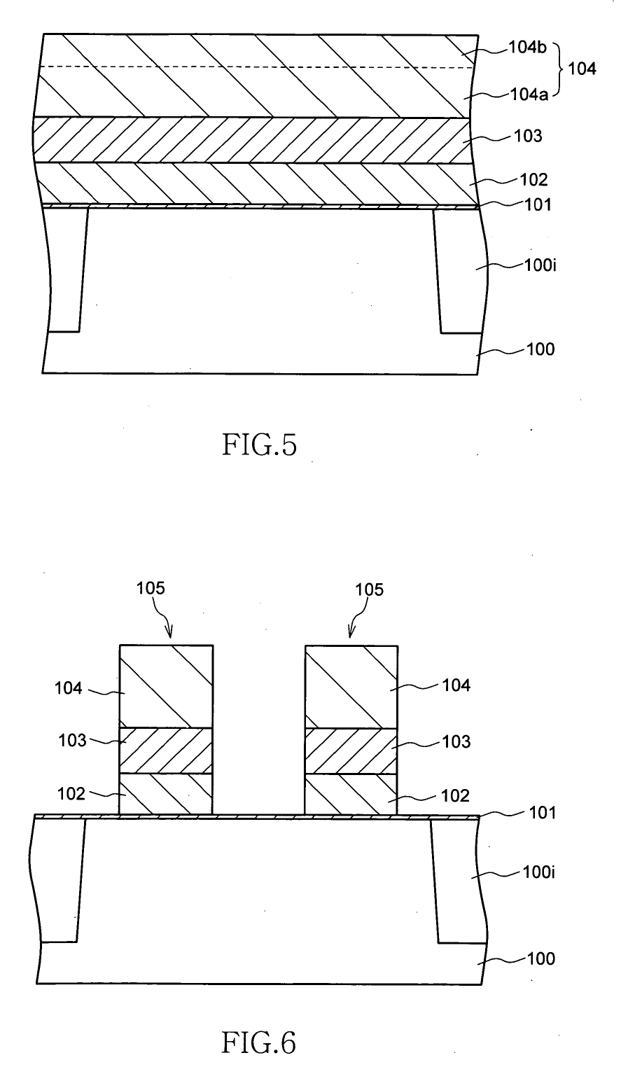

Next, as shown in FIG. 5, a cap insulating film 104 composed of layered silicon nitride film 104a and silicon oxide film 104b is formed on the metal film 103.

The cap insulating film 104 is then patterned into the shape of a gate electrode by a photolithographic technique, and the layered metal film 103 and silicon film 102 are processed by dry etching using the patterned cap insulator film 104 as a mask, thereby completing the polymetal gate electrode 105, as shown in FIG. 6.

A detailed description shall be provided hereunder based on the steps shown in FIGS. 2 and 3. The amorphous silicon film 102 and the silicon oxide film 10 are connected and formed inside the same CVD apparatus in the manner described hereafter.

First, a semiconductor substrate 100 in the state shown in FIG. 1 is introduced into a reaction chamber that has been set to a prescribed temperature and is within an LP-CVD apparatus, and the air within the reaction chamber is expelled to yield a vacuum state. The semiconductor substrate 100 is inserted while the interior of the reaction chamber is set to a desired temperature in a range of about 450 to 550° C., and once the internal temperature of the reaction chamber has subsequently stabilized, a flow of monosilane (SiH₄) gas is delivered into the chamber at a rate of about 1800 to 2000 cc/min while the pressure-control valve is fully open, and the gas flow is held stable for a period of about 30 to 120 seconds (preferably 60 seconds). The pressure-control valve is then controlled to raise the pressure of the reaction chamber to about 80 to 120 Pa (preferably 90 Pa). In this state, a flow of phosphine (PH₃) gas is delivered into the chamber at a rate of about 180 to 190 cc/min, and a silicon film (doped amorphous silicon film) 102 containing phosphorus in a concentration of about 2×10²⁰ to 6×10²⁰ atoms/cm³ is deposited to a desired thickness (about 20 to 100 nm). The flow of phosphine (PH₃) gas does not need to be delivered if the silicon film is not doped with impurities (non-doped). If a non-doped silicon film 102 is formed, impurity doping is performed in a later step by ion implantation or another method.

The introduction of the reaction gas (monosilane gas and phosphine gas) used in the formation of the silicon film 102 is then stopped, whereupon the reaction gas is immediately exhausted. A flow of a gas mixture of oxygen (O₂) gas diluted by Ar gas or another other inert gas to a concentration of about 1 to 5% is delivered into the reaction chamber at a rate of about 3000 cc/min for about 60 to 180 seconds to form a silicon oxide film 10 on the surface of the amorphous silicon film 102. At this time, the internal temperature of the reaction chamber is kept at about 450 to 550° C., and the internal pressure of the reaction chamber is set to about 25 to 120 Pa. The silicon oxide film 10 formed in this manner is an ultra-thin oxide film layer formed on the outermost surface of the silicon film 102.

The concentration of the oxygen (O₂) gas is set to 1 to 5% because if the concentration of the oxygen (O₂) gas is too low, the secondary growth of minute silicon nuclei due to migration on the surface of the amorphous silicon film 102 will be inadequately suppressed, and a risk is thus presented in that a silicon oxide film 10 that does not function efficiently as a stopper film will be formed. Conversely, if the concentration of the oxygen (O₂) gas is too high, a risk is presented in that the removal of the thickly formed silicon oxide film 10 by acid cleaning will be less controllable. In contrast, and due to the fact that the oxidized atmosphere to which the silicon film is exposed has a relatively low temperature and a low partial pressure, a thin oxide film formed under the conditions described above will be formed only on the outermost surface of the silicon film 102 and will be extremely thin (about 0.5 to 1.5 nm). The oxygen concentration of the resulting silicon oxide film is about 1×10²¹ to 1×10²² atoms/cm³. A thin silicon oxide film 10 can thus be formed wherein migration on the surface of the amorphous silicon film 102 is minimized and secondary growth of minute silicon nuclei can be prevented.

The mixture of oxygen gas and Ar gas is exhausted from the reaction chamber after the silicon oxide film 10 has been formed, and the inside of the reaction chamber is then purged by an inert gas (N₂ gas). The line gas remaining within the gas piping through which the reaction gas is fed to the reaction chamber is also exhausted and purged by an inert gas. In gas-line purging, discharging and purging are performed repeatedly several times via a vent line. The inside of the reaction chamber is then returned to atmospheric pressure, and the semiconductor substrate 100 as shown in FIG. 3 is subsequently taken out from the reaction chamber. A period of about 30 to 40 minutes is required for the above-described gas-line purging, during which time the semiconductor substrate 100 is kept inside the reaction chamber, which is at a low pressure (about 1 to 90 Pa). However, according to the present embodiment, the silicon oxide film 10 is formed on the surface of the amorphous silicon film 102 before the gas-line is purged. Therefore, migration on the surface of the amorphous silicon film 102 can be minimized, and the secondary growth of minute silicon nuclei can thus be prevented.

In other words, directly after the amorphous silicon film 102 has been formed, minute silicon nuclei are formed on the surface of the amorphous silicon film 102 while the reaction gas used in the film formation is being exhausted from the reaction chamber. In this state, the gas line is purged further, and when the inside of the reaction chamber is retained at a low pressure, these minute silicon nuclei usually gradually grow (secondary growth) due to migration on the surface of the amorphous silicon film 102. However, according to the present embodiment, further growth of the silicon nuclei can be prevented by covering the surface of the amorphous silicon film 102 with a silicon oxide film 10 before these minute silicon nuclei grow to be large. The minute silicon nuclei before secondary growth have substantially no effect on the state of the surface of the metal film 103 and cap insulating film 104 formed thereon, and the metal film 103 and cap insulating film 104 can be formed with the surface condition being essentially devoid of irregularities. Accordingly, patterning and etching can satisfactorily be performed thereafter, and short-circuiting between the gate electrodes can therefore be prevented.

(Second Embodiment)

Next, as a second embodiment, a description shall be provided of the present invention used in the bottom electrode of the cylinder-shaped capacitor as an example.

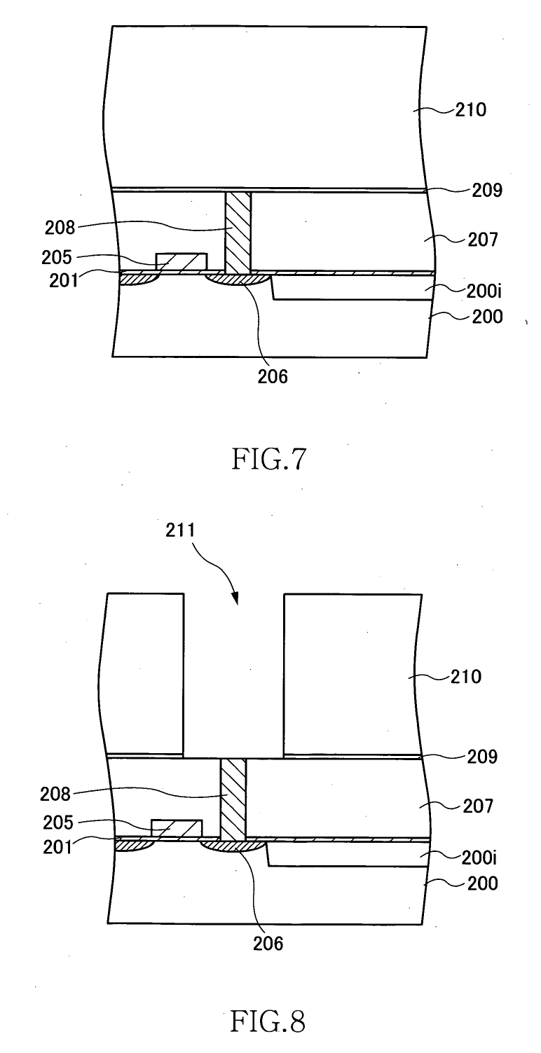

FIGS. 7 through 12 are partial cross-sectional views showing the steps of the method for manufacturing a semiconductor device according to the present embodiment, and show the steps for formation up to the bottom electrode part of the capacitor.

As shown in FIG. 7, an element-separating insulation film 200i is formed on a semiconductor substrate 200 using a known STI formation technique or the like, a gate insulating film 201 is formed on the entire surface, and a transistor gate electrode 205 and a diffusion layer 206 are subsequently formed in the element region. Next, an interlayer insulation film 207 is formed on the entire surface and a contact plug 208 connected to the diffusion layer 206 is subsequently formed. An etching stopper film 209 and a cylinder interlayer film 210 for forming a cylinder-shaped capacitor are then formed in the stated order. The cylinder interlayer film 210 is formed using a silicon oxide film.

Next, as shown in FIG. 8, the cylinder interlayer film 210 is etched to form an opening using a mask not shown in the drawing, with the etching stopper film 209 acting as a stopper. Any etching-stopper film 209 remaining at the bottom of the opening is then removed, the upper part of the contact plug 208 is exposed, and a cylinder hole 211 having the shape of the bottom electrode of a capacitor is formed.

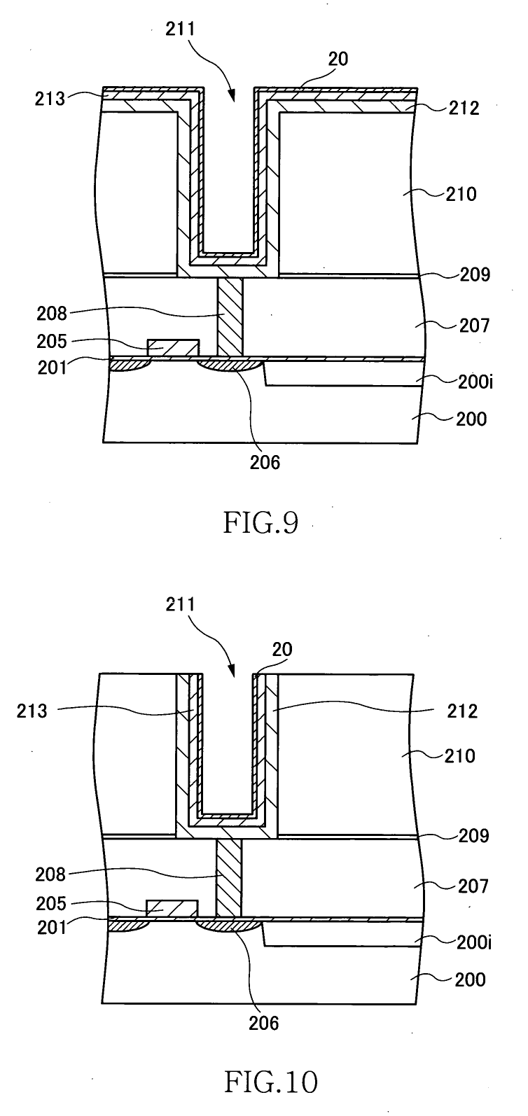

Next, as shown in FIG. 9, an amorphous silicon film 212, which is the ground electrode of the bottom electrode of the capacitor and which is doped with impurities, and a non-doped amorphous silicon layer 213, which will later be subjected to an HSG treatment, are formed in the stated order within the cylinder hole 211 and on the cylinder interlayer film 210. A silicon oxide film 20 that acts as a stopper film for minimizing migration on the surface of the amorphous silicon film 213 is then formed on the amorphous silicon film 213 within the same reaction chamber in which the amorphous silicon films 212 and 213 were formed. The conditions under which the silicon oxide film 20 is formed are the same as those in the first embodiment described above. In addition, the thickness of the silicon oxide film 20 is preferably set to about 0.5 to 1.5 nm, as in the abovementioned first embodiment.

Next, the semiconductor substrate is taken out from the reaction chamber and, as shown in FIG. 10, the silicon oxide film 20 as well as the amorphous silicon films 212, 213 on the cylinder interlayer film 210 are etched back and removed.

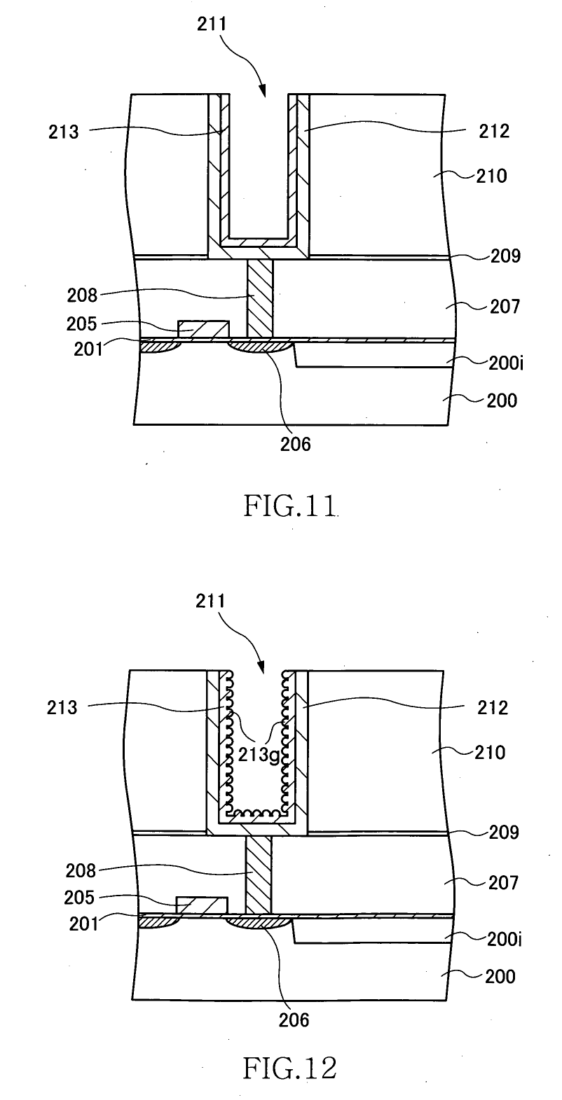

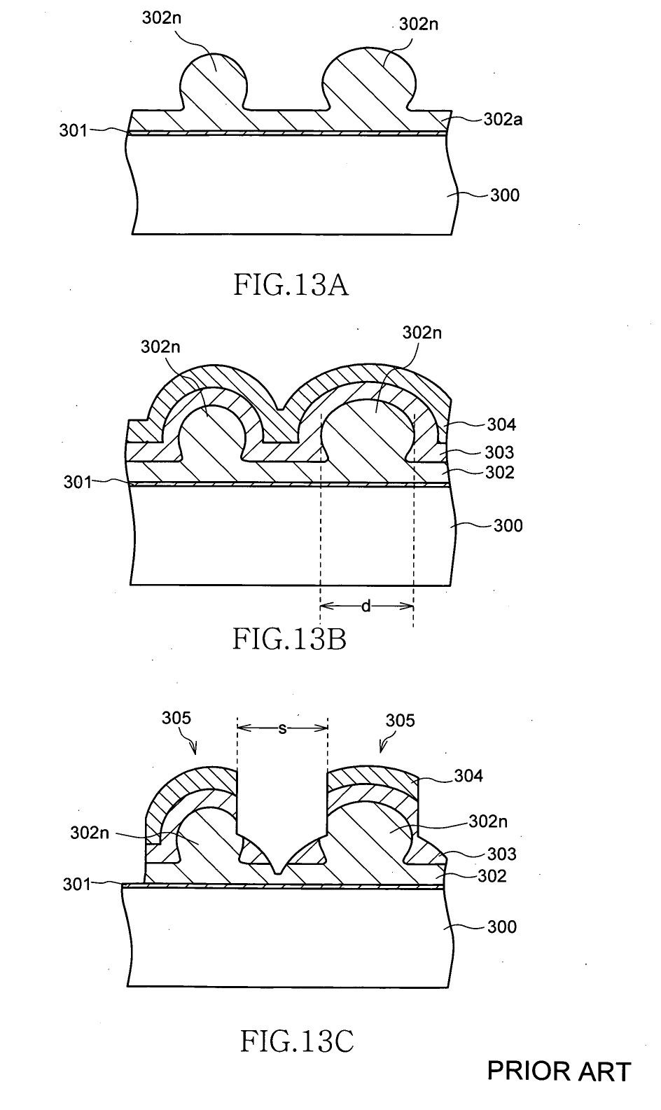

Next, as shown in FIG. 11, the silicon oxide film 20 (see FIG. 10) within the cylinder hole 211 is removed by acid cleaning, and, as shown in FIG. 12, an HSG treatment is then performed on the amorphous silicon film 213 within the cylinder hole 211. Hemispherical grains 213g are thereby formed on the surface of the amorphous silicon film 213. Next, annealing is performed in an atmosphere of PH₃ gas or the like at a temperature of about 650 to 750° C. to convert the amorphous silicon films 212 and 213 to polysilicon, as well as to dope the surface of the silicon film 213 (hemispherical grains 213_{g}) with phosphorus. A capacitor bottom electrode composed of silicon films 212, 213 whose surfaces are provided with hemispherical grains 213_{g} is thereby completed. The silicon oxide film 20 may be removed before the amorphous silicon films 212, 213 are etched back.

Therefore, in the second embodiment as well, once the amorphous silicon films 212, 213 have been formed, the surface of the amorphous silicon film 213 is covered with a silicon oxide film 20 before the minute silicon nuclei, which are formed on the surface of the amorphous silicon film 213 while the reaction gas used in the formation of the films is exhausted from the reaction chamber, undergo secondary growth and become large due to migration on the surface of the amorphous silicon film 213. The silicon nuclei are thereby prevented from growing any larger. Therefore, by removing the silicon oxide film 20 before the HSG treatment is performed on the amorphous silicon film 213, the HSG treatment can be performed on the amorphous silicon film 213 whose surface is substantially devoid of irregularities. Accordingly, the sizes and shapes of the resulting hemispherical grains 213g can be made substantially uniform. It is thus possible to prevent local electric field concentration on the bottom electrode, and to minimize increases in the leak current of the capacitive insulating film formed thereon.

While preferred embodiments of the present invention have been described hereinbefore, the present invention is not limited to the aforementioned embodiments and various modifications can be made without departing from the spirit of the present invention. It goes without saying that such modifications are included in the scope of the present invention.

For example, a thin silicon oxide film was used in the above embodiments as the stopper films 10, 20 for minimizing migration on the surface of the amorphous silicon film, but other films can be used as long as they are capable of minimizing migration.

The inert gas used to dilute the oxygen gas when the silicon oxide films 10, 20 are formed may also be helium gas (He), nitrogen gas (N₂), neon (Ne) krypton (Kr), xenon (Xe), or another gas other than Ar gas.

Furthermore, N₂O gas, for example, may be used instead of oxygen gas when forming the stopper films 10, 20.

What is claimed is:

1. A method for manufacturing a semiconductor device, comprising:
a first step for forming an amorphous silicon film on a semiconductor substrate;
a second step for forming a stopper film on a surface of said amorphous silicon film to prevent migration of said surface of said amorphous silicon film; and
a third step for removing said stopper film from the surface of said amorphous silicon film.

2. The method for manufacturing a semiconductor device as claimed in claim 1, wherein said first and second steps are performed consecutively within the same reaction chamber.

3. The method for manufacturing a semiconductor device as claimed in claim 2, wherein said amorphous silicon film is formed by introducing a reaction gas for forming said amorphous silicon film into said reaction chamber, whereupon said stopper film is formed immediately after said reaction gas is exhausted from said reaction chamber by introducing a gas for forming said stopper film into said reaction chamber.

4. The method for manufacturing a semiconductor device as claimed in claim 1, wherein said stopper film is a silicon oxide film.

5. The method for manufacturing a semiconductor device as claimed in claim 2, wherein said stopper film is a silicon oxide film.

6. The method for manufacturing a semiconductor device as claimed in claim 3, wherein said stopper film is a silicon oxide film.

7. The method for manufacturing a semiconductor device as claimed in claim 1, wherein
the gas for forming said stopper film is a mixed gas of an inert gas and oxygen gas; and
said stopper film is a silicon oxide film.

8. The method for manufacturing a semiconductor device as claimed in claim 7, wherein the concentration of said oxygen gas contained in said composite gas is 1 to 5%.

9. The method for manufacturing a semiconductor device as claimed in claim 4, wherein the oxygen concentration of said silicon oxide film is 1×10²¹ to 1×10²² atoms/cm³.

10. The method for manufacturing a semiconductor device as claimed in claim 4, wherein the thickness of said silicon oxide film is 0.5 to 1.5 nm.

11. The method for manufacturing a semiconductor device as claimed in claim 5, wherein the thickness of said silicon oxide film is 0.5 to 1.5 nm.

12. The method for manufacturing a semiconductor device as claimed in claim 6, wherein the thickness of said silicon oxide film is 0.5 to 1.5 nm.

13. The method for manufacturing a semiconductor device as claimed in claim 7, wherein the thickness of said silicon oxide film is 0.5 to 1.5 nm.

14. The method for manufacturing a semiconductor device as claimed in claim 8, wherein the thickness of said silicon oxide film is 0.5 to 1.5 nm.

15. The method for manufacturing a semiconductor device as claimed in claim 9, wherein the thickness of said silicon oxide film is 0.5 to 1.5 nm.

16. The method for manufacturing a semiconductor device as claimed in claim 4, wherein said silicon oxide film is formed in an atmosphere having a temperature of 450 to 550° C. and a pressure of 25 to 120 Pa.

17. The method for manufacturing a semiconductor device as claimed in claim 1, wherein, after said second step, the pressure within said reaction chamber is held at 1 to 90 Pa, the gas within the reaction chamber and the gas within the piping through which gas is fed to the reaction chamber are exhausted, and the inert gas is purged.

18. The method for manufacturing a semiconductor device as claimed in claim 1, comprising:
a fourth step for forming a metal film on said amorphous silicon film following the third step; and
a fifth step for patterning said metal film and said silicon film to form a gate electrode.

19. The method for manufacturing a semiconductor device as claimed in claim 1, comprising a fourth step for performing an HSG treatment on said amorphous silicon film following the third step.
